(19) United States
(12) Patent Application Publication
(10) Pub. No.: US 2002/0042200 A1
(43) Pub. Date: Apr. 11, 2002

(54) Method for conditioning polishing pads

(76) Inventor: Clyde Fawcett, Claymont, DE (US)

Correspondence Address: Rodel Holdings, Inc., Suite 1300, 1105 North Market Street, Wilmington, DE, 19899, US

(21) Appl. No.: 09/965,777

(22) Filed: Sep. 28, 2001

Related U.S. Application Data
(60) Provisional application No. 60/237,464, filed on Oct. 2, 2000.

(51) Int. Cl. H01L 21/302

(52) U.S. Cl. 438/692

(57) ABSTRACT

A method for conditioning a polishing pad includes, pressing a conditioning surface of a conditioning pad comprising a first polymer against a polishing surface of the polishing pad comprising a second polymer, and producing relative motion between the pads such that measured characteristics of the polishing surface are changed.

### CROSS REFERENCE TO RELATED APPLICATION

This application claims the benefit of provisional application 60/237,464 filed Oct. 2, 2000.

### FIELD OF THE INVENTION

This invention relates to polishing pads used in plianarizing substrates. In particular, this invention relates to the conditioning of polishing pads.

### BACKGROUND OF THE INVENTION

Semiconductor chips are manufactured by forming consecutive layers on a semiconductor wafer substrate. During the manufacturing process, the semiconductor wafer substrate is often polished to remove unwanted materials on the surface of the wafer. One or more of the layers are usually planarized and/or polished in a process known as “chemical-mechanical polishing” (CMP), which removes material such as dielectric, metal or polysilicon, to form the necessary interconnects, insulation and various components of the integrated circuit.

In the fabrication of integrated circuits, CMP typically planarizes and/or polishes the surface of substrates, such as conventional silicon-based materials, e.g., polysilicon, single-crystalline silicon, silicon dioxide, low-k inorganic and organic materials, metal interconnects and layers, and the like, by moving the substrate across a polishing medium. In a typical arrangement, a wafer substrate is supported by a carrier, which presses the substrate against the surface of a moving polishing pad. The wafer substrate and the polishing pad are then moved over one another. A slurry is introduced on the polishing pad. The polishing pad has an abrasive surface so that movement of the wafer and the polishing pad over one another gradually removes the layer. The process is continued until the desired surface of the substrate is planarized or in some cases completely removed. The pad should uniformly remove material from the surface of the substrate.

The surface of a new polishing pad can have topographical variations or other surface properties that cause inconsistent and low performance during polishing of wafers. Primary conditioning or preconditioning refers to conditioning a newly manufactured polishing pad prior to use on a polisher. Primary conditioning of the pad surface prior to use is usually necessary to reduce the TTV (Total Thickness Variation) and to change the surface roughness so that a uniform, planar surface is produced on the wafer being polished.

Diamond type primary conditioning, in which the pad is conditioned with a diamond conditioning disk prior to use, is typically carried out. However, this method also abrades the surface of the polishing pad by removing a layer of the polishing pad surface and may not produce the desired leveling needed for flat pad profiling. Over time using a diamond conditioning tool on the pad can change the pad surface to an unusable height, profile, or texture, and the pad will have to be discarded and replaced. Diamond granules may also eventually be lost from the conditioning disk and become mixed with the slurry. The loose diamond granules in the slurry can scratch the polished surface of the wafer. Also, the diamond conditioning disk must be discarded once the diamonds are lost from the surface. In addition, diamond conditioning methods typically use small tools that only cover part of the wafer track area of the polishing pad.

During the polishing process, the properties of the polishing pad can change. Slurry particles and polishing byproducts accumulate on the surface of the pad. Polishing byproducts and morphology changes on the pad surface can affect the properties of the polishing pad and cause the polishing pad to suffer from a reduction in both its polishing rate and performance uniformity. However, pad reconditioning restores the polishing pad's properties by re-abrading or otherwise restoring the surface of the polishing pad. Reconditioning, or secondary conditioning, of the polishing pad is often conducted on the production polishing apparatus concurrently or simultaneously while wafer(s) are being polished and/or intermittently between the polishing runs. Polishing pad conditioning on the polishing apparatus used in production is collectively referred to as secondary conditioning includes “in-situ” (conditioning during wafer polishing run) and “ex-situ” (conditioning between wafer polishing runs).

During the reconditioning process, a conditioner is used to recondition the surface of the polishing pad. Conditioning materials include, for example, hard materials, such as diamond, serrated steel, or ceramic bits, softer materials, such as brushes with stiff bristles, or soft bristle brushes, as well as pressurized sprays. Although each material may be used with each pad type, the type of conditioner used typically depends on the pad type. For example, hard polishing pads, typically constructed of synthetic polymers such as polyurethane, are reconditioned with harder materials, intermediate polishing pads with extended fibers are typically reconditioned with softer materials, and soft polishing pads, such as those made of felt, are typically reconditioned still softer materials or with a pressurized spray.

Chemical mechanical polishing processes require a significant investment in operational consumables such as pads and slurries. Thus, the secondary conditioning methods (in-situ conditioning and ex-situ conditioning) need to be accomplished with as little removal or height change to the pad, which will help in maintaining a consistent liquid volume at the wafer surface and pad area and prolong the lifetime of the pad. A conditioning system that maintains removal rates and uniformity of wafer substrates, while reducing the rate of irreversible wear on the pad surface caused by polishing and conditioning has been long sought. Therefore, a need exists for a method that maintains removal rates and uniformity in processing wafer substrates, while reducing the rate of irreversible wear on the pad surface caused by polishing and conditioning.

### SUMMARY OF THE INVENTION

The invention includes a method for conditioning a polishing pad, the method comprising the step of conditioning the polishing surface of the polishing pad with a conditioning pad having a conditioning surface by pressing the conditioning surface of the conditioning pad comprising a first polymer against the polishing surface of the polishing pad comprising a second polymer, and producing relative motion between the pads such that the characteristics of the polishing surface of the polishing pad are changed.

Embodiments of the invention will now be described by way of example with reference to the following detailed description.

### DETAILED DESCRIPTION

The method can be used for either new pad conditioning (primary conditioning) or during wafer polishing using in-situ and ex-situ conditioning (secondary conditioning) of the pad. In primary conditioning of a new pad surface, the higher down force of the of a polishing head is used, especially in an area at least as large as the oscillating range (wafer track area), which is the pad surface region circumscribing the repeating polish contact area, and preferably also over the surrounding areas of the wafers track for complete leveling of pad area.

Primary conditioning of an as-manufactured pad mounted on the polishing platen provides improved leveling or flatness (TTV—total thickness variation) of the pad surface. This method can also help to reduces the surface roughness of the polishing pad surface, thereby improving the surface smoothness and lowering defects in the production of polished substrates such as glass, wafers made of silicon, germanium, or gallium arsenide, and metallic sheets, such as copper, tungsten, aluminum, nickel coated aluminum, and connect devices made from these materials, in addition to disk drive substrates.

Secondary conditioning uses a conditioning arm or other conditioning tool, which can not use the higher down forces used with in primary conditioning. This method assists in the removal of by-product or build-up (pad glazing) that forms during polishing for improved polishing pad productivity over the life of the polishing pad.

Either pre-conditioning or secondary conditioning (in-situ conditioning or ex-situ conditioning) may be carried out with any state of the art polishing apparatus. This equipment is readily available and well-known to those skilled in the art. One example is the Siltec 3800 (Cybec Corp.) polisher which is used in many base silicon wafer polishing houses like reclaim wafer production all the way up to a CMP polishing tool like the MIRRA® polishing tool (Applied Materials). The method may be carried out using a polishing apparatus having multiple platen and heads, switching from one conditioning method to another would be helpful in response to various progress stages in the preparation of wafer devices.

The conditioning pad is removably fixed with its conditioning surface in coplanar relationship to a carrier for the polishing pad. The carrier is provided on the polishing apparatus and can be either the polishing head or wafer carrier, or a separate conditioning arm.

The method of the invention comprises pressing the polishing surface of a conditioning pad as a conditioning tool with down force against the polishing surface of the polishing pad, and optionally applying a fluid solution or dispersion therewith. In one embodiment, the method comprising the step of conditioning the polishing surface of the polishing pad with a conditioning pad having a conditioning surface by pressing the conditioning surface of the conditioning pad against the polishing surface of the polishing pad, and producing relative motion between the pads such that the characteristics of the polishing surface of the polishing pad are changed.

According to another embodiment, the first polymer and the second polymer each have the following properties:

a density of greater than 0.5 g/cm³;

a selected critical surface tension to provide a corresponding hydrofilicity;

a tensile modulus of 0.02 to 5 GigaPascals;

a ratio of the tensile modulus at 30° C. to the modulus at 60° C. in the range of about 1.0 to 2.5;

a hardness of 25 to 80 Shore D;

a yield stress of about 300 psi (about 2.1×10⁵ kg/m²) to about 6000 psi. (about 4.22×10⁶ kg/m²); and

a tensile strength of about 500 psi (3.52×10⁵ kg/m²) to about 15,000 psi (about 1.05×10⁷ kg/m²), and an elongation to break up to 500%.

In certain embodiments of the invention, both the conditioning pad and the polishing pad comprise polyurethane polymers.

An apparatus used in the chemical-mechanical polishing (CMP) of substrates typically comprises a polishing pad and a means to support the pad (also referred to as a “platen”); a means of holding a wafer or substrate to be polished (also referred to as a “wafer carrier”) that retains the substrate in a parallel or co-planar relationship with the upper surface of the polishing pad; and a drive means for rotating and/or translating the substrate. The control system on the CMP apparatus applies pressure to the wafer pressing against the pad surface with a prescribed or predetermined amount of force. The motion of the wafer is arbitrary, but is typically rotational or orbital. Further, preferably, the motion of the polishing pad is either rotational or orbital. Slurry is required for polishing and is delivered either directly to the surface of the polishing pad or through holes and grooves in the pad polishing directly to the surface of the substrate. While the substrate and polishing pad are rotating, the substrate is typically oscillated back and forth across the polishing pad. The oscillating motion covers a distance called an oscillating range and is performed at an oscillating velocity. While the polishing is being performed, the polishing slurry may be recycled.

The CMP apparatus also comprises a conditioning arm, which can be moved over an area at least as large as the polishing substrate contacting area on the polishing pad. A conditioning pad or conditioning tool is mounted on the conditioning arm. The conditioning apparatus provides for a driven rotation of the conditioning pad and translating the conditioning pad with down force to frictionally engage the surface of the conditioning pad against the surface of the polishing pad.

The conditioning pad may be removably mounted on the conditioning arm by mechanical fastening, clamping, or preferably mounted on a conditioning arm, or on the polishing head itself, by the use of a commercially available pressure sensitive adhesive film. The film adheres the back side of the conditioning pad to the head or contact surface of the arm. Typically, when a polishing apparatus equipped with a conditioning arm is used, a 4-inch diameter (about 10 cm) round-shaped conditioning pad is used. An example of an apparatus providing a 4-inch (about 10 cm) diameter conditioning arm is the Strasbaugh, Model 6DS-SP CMP polisher. Polishing machines that provide a wafer surround ring-type unit are manufactured by Applied Materials under the MIRRA® designation and under the EBARA® designation. The surround ring can also be used as a pre- and in-situ pad conditioner using conditioning pads, such as the polishing pads supplied by Rodel, Newark, Del.

The polishing surface of the polishing pad on the platen is brought in contact with the polishing surface of the conditioning pad. One or both of the pads is moved so that there is relative motion between the pads. Typically, one or both of the pads is moved while the polishing surface of the conditioning pad is pressed against the polishing surface of the polishing pad. Typically the motion of either or both pads is either rotational or orbital. The pads are pressed together with the down force typically applied in wafer polishing, i.e. typically about 0.5 psi (about 350 kg/m²) to about 10 psi (about 7,030 kg/m²), preferably about 1 psi (about 703 kg/m²) to about 5 psi.(about 3515 kg/m²).

The use of a polishing slurry, a cleaning solution, or deionized (Dl) water in combination with the conditioning pad is preferred, and provides flushing, and re-dispersion of the glaze material, enabling the dislodging or removal as well as transport of residue away from the polishing pad surface. A variety of abrasive polishing slurries are available commercially. One useful slurry type is adapted for copper wafer polishing. It is preferred to provide a relatively higher slurry pumping rate to the conditioning site, as compared to flow rates utilized during polishing of substrates. This higher flow rate improves the conditioning. Distilled water may be used for cleaning. A cleaning solution comprising some citric acid in addition to other ingredients may also be used during conditioning of polishing pads in a copper CMP process. Potassium hydroxide and other ingredients can be used in some base silicon processes.

The conditioning method may be carried out carried out using commercially-available composite or non-composite polishing pads as the conditioning pad. A composite fiber-polymer type pad appears to provide a dual pad and brushing conditioning action. In conjunction with a flowing loose abrasive or cleaning/abrasive or cleaning fluid, the composite pad exhibits excellent glaze removal and surface conditioning. Commercially available polyurethane composite polishing pads are adaptable for in-situ or ex-situ conditioning by cutting a larger pad down to any desired size, typically such as a 4-inch (about 10 cm) diameter disc, a ring-shape disc or a wafer-shape disc, which is suited to fit in the conditioning arm or polishing head of currently polishing machines in use. Preferably, for primary conditioning, the polyurethane in the conditioning pad is at least as hard as, or harder than, the polyurethane in the polishing pad and the conditioning surface of the conditioning pad (which is the same as the polishing surface of the conditioning pad) is harder than, or at least as hard as, the polishing surface of the polishing pad.

The terms “conditioning tool” and “conditioning pad” are used interchangeably. The term non-composite means a homogeneous, non-fiber, non-abrasive impregnated polymeric pad. A composite pad is referred to as a fiber/polymer or abrasive/polymer composite.

The conditioning pad may comprise a continuous matrix derived from one of the following polymer types: acrylated urethanes; acrylated epoxys; ethylenically unsaturated organic compounds having a carboxyl, benzyl, or amide functionality; aminoplast derivatives having a pendant unsaturated carbonyl group; isocyanurate derivatives having at least one pendant acrylate group; vinyl ethers; urethanes; polyacrylamides; ethylene/ester copolymers or acid derivatives thereof; polyvinyl alcohols; polymethyl methacrylates; polysulfones; polyamides; polycarbonates; polyvinyl chloride; epoxys; copolymers of the above; or combinations thereof. The polymer is preferably applied as a conditioning pad to a polishing pad constructed of the same polymer-type. A conditioning pad made from one of the above polymer-types can be used to condition a polishing pad that is constructed of a different polymer type.

Preferred molded conditioning pads comprise urethane, carbonate, amide, sulfone, vinyl chloride, acrylate, methacrylate, vinyl alcohol, ester, or acrylamide moieties. The pad material can be porous or non-porous. In one embodiment, the matrix is non-porous; in another embodiment, the matrix is non-porous and free of fiber reinforcement.

In another embodiment, the molded conditioning pad is a compounded polymer having soft and hard domains. The conditioning surface layer material comprises a plurality of rigid domains that resists plastic flow during polishing; and a plurality of less rigid domains that are less resistant to plastic flow during polishing. The rigid phase size in any dimension (height, width or length) is preferably less than 100 microns, more preferably less than 50 microns, yet more preferably less than 25 microns and most preferably less than 10 microns. Similarly the non-rigid phase is also preferably less than 100 microns, more preferably less than 50 microns, more preferably less than 25 microns and most preferably less than 10 microns. Preferred dual phase materials include polyurethane polymers having a soft segment (which provides the non-rigid phase) and a hard segment (which provides the rigid phase). The domains are produced during the forming of the polishing layer by a phase separation, due to incompatibility between the two (hard and soft) polymer segments.

Other polymers having hard and soft segments may also be appropriate, including ethylene copolymers, copolyester, block copolymers, polysulfones copolymers and acrylic copolymers. A heterogeneous matrix comprising hard and soft domains in the conditioning pad material can also be created: by hard and soft segments along a polymer backbone; by crystalline regions and non-crystalline regions within the pad material; by alloying a hard polymer with a soft polymer; or by combining a polymer with an organic or inorganic filler. Useful such compositions include copolymers, polymer blends, interpenetrating polymer networks, fixed/dispersed abrasive particle-impregnated polymers, e.g. silica-filled pads, and the like.

The non-composite conditioning pads can be designed with a conditioning surface comprising macro-channels or macro-indentations. This texture can be imparted by lathe cutting tools, or formed by the molding, where the macro-texture is provided by thin-walled protrusions extending into the mold. The mold protrusions preferably provide an inverted image that is complementary to the intended macro-texture design or configuration. The macro-indentation(s) is(are) useful in providing large flow channels for the polishing fluid, used during the conditioning operation. After forming the pad's conditioning layer, including at least a part of the macro-texture, the contact surface can be further modified by adding a micro-texture. The micro-texture is preferably created by moving the intended conditioning layer surface against the surface of an abrasive material such as a diamond conditioning tool. Macrotexture configuration techniques that can be applied to the conditioning pad are disclosed in U.S. Pat. Nos. 5,081,051; 5,216,843; 5,329,734; 5,527,215; 5,536,202; 5,547,417; 5,609,517; 5,628,862; 5,645,469; 5,664,989; 5,807,165; 5,882,251; 5,888,121; and 6,022,268.

The primary conditioning pad typically comprises, a fiber-polymer composite, an abrasive-filled polymer composite, or a non-composite polymeric pad. Conditioning pads for in situ conditioning can be formed by adapting polishing pads in the form resembling smaller-scale polishing discs, or rings, such as can be died out from larger sections of a polishing pad, and molded, or skived in section thicknesses ranging from 20-500 mils and from 3 to 20 inches (about 7.5 cm to 51 cm) in diameter.

Non-composite conditioning pads are preferably made of crosslinked polyurethane, from reaction injection molding of isocyanate prepolymers, e.g., di-isocyanate and tri-isocyanate prepolymers, chain extenders and other co-reactants. The most widely used di-isocyanate prepolymers include 2,4- and 2,6-toluene diisocyanate and 4,4′- and 2,4′-diphenyl methane diisocyanate. The isocyanate prepolymer preferably comprises an average isocyanate functionality of at least two but not generally more than 4. The more preferred polymer is a fully chain extended polymer, using diols or diamines, e.g. 1,4-butane diol and diethyltoluenediamine, respectively, and similar compounds.

An isocyanate prepolymer is generally reacted to a second prepolymer having an isocyanate reactive moiety. Preferably, the second prepolymer comprises, on average, at least two isocyanate reactive moieties. Isocyanate reactive moieties include amines, particularly primary and secondary amines, and polyols; preferred prepolymers include diamines, diols and hydroxy functionalized amines. A segmented polyurethane containing soft-segment co-reactants such as hydroxy-terminal polyethers or polyesters.

The non-composite conditioning pads can be porous or non-porous. Porous, or “poromeric” conditioning pads should have a working surface comprised of a microporous polymeric material that contains open cells that have their largest opening at the work surface and are deep enough to carry a relatively large quantity of slurry. The pad is made by solvent/nonsolvent polymer coagulation, such as disclosed in Hoffstein, U.S. Pat. No. 4,841,680.

A non-composite multi-layered conditioning pad that comprises a relatively more rigid backing layer adjacent to a resilient conditioning layer can be used. The rigid layer imparts a dimensional stability and controlled rigidity to the polishing layer. The resilient layer is used as the conditioning contact surface and provides a uniform pressure against the polishing pad surface. During conditioning, the rigid layer and the resilient layer apply an elastic flexure pressure to the polishing pad to induce controlled flex in the conditioning layer to conform to the global topography of the polishing surface of the polishing pad while maintaining a controlled rigidity over the local topography of the polishing pad surface. The compositions comprise (a) 70% by weight of a first phase consisting of a thermoplastic poly(alkylene terephthalate) polyester having an intrinsic viscosity of at least 0.72, and (b) 30% by weight of a second phase consisting of a modified block copolymer for supertoughening the composition, wherein said block copolymer consists of the structure A-B-A wherein each A block is at least predominantly a polymerized styrene block having a weight average molecular weight of about 7,200 and each B block is a selectively hydrogenated butadiene block having a weight average molecular weight of about 35,000, said modified block copolymer having a residual unsaturation less than 2% based on the original ethylenic unsaturation prior to hydrogenating and grafted thereto from 0.8% to 2.6% by weight of maleic anhydride, substantially all of said anhydride being grafted to said block copolymer on said B blocks. A method to produce this pad is disclosed in Gelles, U.S. Pat. No. 5,281,663, incorporated herein by reference.

An alternative non-composite conditioning pad is a cast or molded pad comprising an upper surface and a lower surface, substantially parallel to one another, in which the pad has enhanced flexibility produced by scoring of either or both surfaces. The pad thickness is generally greater than 500 microns. The scoring creates slits having a depth of less than 90% of the thickness.

A composite conditioning pad can be made according to Reinhardt, U.S. Pat. No. 6,095,902 using polyether prepolymers, polyester prepolymers or a combination of these. The preferred polymers have the following properties:

a density of greater than 0.5 g/cm³, more preferably greater than 0.7 g/cm³, especially greater than about 0.9 g/cm³;

a tensile modulus of 0.02 to 5 GigaPascals;

a ratio of the tensile modulus at 30° C. to the modulus at 60° C. in the range of about 1.0 to 2.5;

a hardness of 25 to 80 Shore D;

a yield stress of about 300 to about 6000 psi (about 2.11×10⁵ kg/m² to about 4.22×10⁶ kg/m²); and/or

a tensile strength of about 500 to about 15,000 psi (about 3.52×10⁵ kg/m² to about 1.05×10⁷ kg/m² and an elongation to break up to 500%.

Mixed ether/ester polyurethane may be produced by addition of a polyether diol and a polyester diol to a solvent, such as N,N′-dimethylformamide, along with a chain extender, for instance 1,4,butanediol. Equimolar amounts of this combination and diphenylmethane 4,4′diisocyanate (MDI) are reacted to form the mixed ether/ester polyurethane. Preferably 15-40% solids are used, more preferably 20-40% solids. A substrate, such as polyester nonwoven fiber felt, or synthetic paper base mat is coated with a solution of the polymer and then the coated substrate is immersed into an aqueous bath to coagulate the polymer. Once the polymer has been sufficiently coagulated, the remaining solvent is leached out and the product is dried. Voids in the composite pad polymer structure can be provided which are vertically oriented. The top skin is then removed by passing the material under a blade, as in skiving, or under a rotating abrasive wheel or cylinder, as in buffing. Once the top skin is removed the underlying pores are exposed and opened to the surface. The slitted composite can optionally be re-coated or impregnated with polyurethane solution and further processed. It is preferred to prepare composite conditioning pads by buffing the as-manufactured surface, such as with a 120-grit abrasive wheel. If more exposed fiber surface is desired, a more coarse abrasive, e.g., an 80-grit wheel can be used.

A layer of the conditioning polymer may be used as such, but preferably is affixed to a backing or supporting layer to form the conditioning pad. For most uses the backing, or substrate, is a flexible sheet material, such as the conventional polishing pad non-woven fibrous backings. Other types of backing may be used, including rigid impermeable membranes, such as polyester film. The substrate serves as a vehicle for handling during processing and to prevent buckling, tearing, or applying the conditioning surface in a non-uniform manner. Also the substrate can be utilized to adjust the elastic properties of the conditioning pad.

Abrasive particles may be a part of the polishing pad layer formed of polyether/ester polyurethane. The abrasive may be selected from any of the known materials conventionally employed for polishing. Examples of suitable materials include diatomite (diatomaceous earth), calcium carbonate, dicalcium phosphate, pumice, silica, calcium pyrophosphate, rouge, kaolin, ceria, alumina and titania, most preferably silica, alumina, titania and ceria. Abrasive particles useful for polishing semiconductor wafers have an average particle size of less than one micron, more preferably less than 0.6 microns.

A preferred material for the conditioning pad is produced by modifying conventional poromeric materials in which a porous thermoplastic resin matrix is reinforced with a fibrous network. The fiber network is preferably a felted mat of polyester fibers or other fibers having a softening point higher than the melting point of the resin. More preferably the materials are urethane impregnated polyester felts. The material is modified by coalescing the resin among the fibers, preferably by heat treatment, to increase the porosity and hardness of the material as well increasing the surface activity of the resin. Polishing aids such as particulate abrasives may be incorporated into the pad material preferably prior to the coalescence of the resin. The abrasive material is preferably selected from the group consisting of silica, cerium oxide, titanium dioxide, silicon carbide and diamond. These materials are disclosed in Budinger, U.S. Pat. No. 4,927,432, incorporated herein by reference. Pads comprising these materials are available under the Suba® trademark, e.g. JR 111, Suba® 500, and Suba® IV, from Rodel, Inc., Newark, Del.

Other conditioning pads that may be used include, for example, microporous urethane pads of the type sold as POLITEX® polishing pads by Rodel, Inc., Newark, Del. These pads have a surface texture derived from the ends of columnar void structures within the bulk of a urethane film which is grown on a urethane felt base.

Polishing pads comprising a surface texture or pattern comprising both large and small flow channels which together permit the transport of polishing slurry containing particles across the surface of the polishing pad, in which the surface texture is produced solely by external means upon the surface of the solid uniform polymer sheet, and methods for making polymeric pads having vertically oriented voids, are disclosed in Cook, U.S. Pat. No. 5,489,233, incorporated herein by reference. The projecting surfaces between said large flow channels are of dimensions ranging from 0.5 mm to 5 mm in largest lateral dimension.

Filled and/or blown composite urethanes such as IC-series and MH-series polishing pads manufactured by Rodel, Inc. Newark, Del. These may contain fixed abrasive particles dispersed in a cured polymer binder made from polymerizable monomers, oligomers and polymers, e.g., ethylenically unsaturated monomers, urethane prepolymers, “acrylated-urethane” monomers, including multi-functional monomers and mixtures thereof.

### Polishing Pads

The polishing pad may be, for example, any of the conditioning pads described above. The polishing pad may be, for example, a fiber-polymer composite, a non-composite polymeric, fixed-abrasive composite or ceramic primary polishing pad. These pads are commercially available and well known to those skilled in the art. Polishing pads are available, for example, from Rodel, Inc., Newark, Del (JR 111, MH pads, IC pads, Suba® 500, Suba® IV, metals 26, POLITEX®, UR100, SPM1000 to SP<6000, etc).

The preconditioning method also supplants wafer preconditioning techniques that use a series of dummy wafers prior to production wafer polishing. The secondary, or in-situ or ex-situ, conditioning method provides a new method for attaining improved pad productivity and extended useful life, and preferably improved consistency of peak polishing performance.

The advantageous properties of this invention can be observed by reference to the following examples, which illustrate, but do not limit, the invention.

### EXAMPLE 1

This example illustrates copper substrate polishing with and without in-situ conditioning.

A CMP polisher manufactured by Strasbaugh, model 6DS-SP equipped with a conditioning arm was used. The conditioning arm is adapted to accept a 4 in (about 10 cm) round conditioner, fixed by pressure sensitive adhesive. A down force of 15 psi (about 10,500 kg/m²) was used and relatively higher slurry flow rate was used rather than the standard polishing flow rate.

A series of copper sheet substrates were polished with a fixed abrasive type pad. The polishing pad was mounted on the platen of the polishing apparatus and preconditioned using a diamond-impregnated conditioning pad. Preconditioning involved three bidirectional sweeps under 3 psi (about 2.1×10³ kg/m²) of force. A polishing solution was applied at a flow rate of 125 ml/min. The platen speed was 90 RPM, the wafer carrier speed was 60 RPM, and wafer down-force was 3 psi (about 2.1×10³ kg/m²).

A series of 50 copper sheet wafers were polished, and the temperature of the polishing pad, and removal rate monitored with and without in-situ conditioning of the polishing pad. In-situ conditioning was carried out with a Rodel Suba® 500 UP/nonwoven composite as the conditioning pad.

With no in-situ conditioning of the polishing pad during wafer runs, the pad temperature and removal rate reached baseline, and thereafter trended lower between wafers 16 and 40. On application of in-situ conditioning with the Suba® 500 conditioning pad, the temperature and removal rates for the fixed-abrasive pad returned to baseline, indicating an improvement in the polishing pad performance.

### EXAMPLE 2

A copper pattern wafer “931 MASK” was treated using a fixed abrasive and polishing solution. The time to clear the copper layer using a pad that had been in-situ conditioned using a Rodel SUBA® 500 conditioning pad was 650 seconds, compared to about 1100 seconds to clear the copper pattern using a polishing pad that had not been in-situ conditioned with a Rodel SUBA® 500 conditioning pad.

### EXAMPLE 3

This example shows removal rate using a fixed abrasive type pad with in-situ conditioning using a composite polymer/fiber conditioning pad.

Three separate sets of copper sheet wafers were used to determine removal rate variation between different polishing runs. In the test, the first 15 wafers were dummy copper wafers used in the break-in of the polishing pad. Each of the 15 dummy wafers was polished for 1 minute. Then prime copper sheet rate wafers run number 16/17, 23/24, 30/31 were monitored for removal rate. Five dummy copper wafers were polished for one minute each between the prime rate copper wafers. In-situ conditioning was carried out during the polishing of both the dummy and prime rate wafers. The temperature remained level during the runs. Removal rates are shown in Table 1

TABLE 1

| | | Polish time | | wafer % |
|---|---|---|---|---|
| RUN # | Wafer | per wafer (sec) | Average RR per min (A) | NU |
| 1 | Dummy | 60 | | |
| 2 | Dummy | 60 | | |
| 3 | Dummy | 60 | | |
| 4 | Dummy | 60 | | |
| 5 | Dummy | 60 | | |
| 6 | Dummy | 60 | | |
| 7 | Dummy | 60 | | |
| 8 | Dummy | 60 | | |
| 9 | Dummy | 60 | | |
| 10 | Dummy | 60 | | |
| 11 | Dummy | 60 | | |
| 12 | Dummy | 60 | | |
| 13 | Dummy | 60 | | |
| 14 | Dummy | 60 | | |
| 15 | Dummy | 60 | | |
| 16 | Rate | 60 | 1279.38 | 5.3% |
| 17 | Rate | 60 | 1308.28 | 2.7% |
| 18 | Dummy | 60 | | |
| 19 | Dummy | 60 | | |
| 20 | Dummy | 60 | | |
| 21 | Dummy | 60 | | |
| 22 | Dummy | 60 | | |
| 23 | Rate | 60 | 1171.04 | 4.1% |
| 24 | Rate | 60 | 1123.98 | 7.1% |
| 25 | Dummy | 60 | | |
| 26 | Dummy | 60 | | |
| 27 | Dummy | 60 | | |
| 28 | Dummy | 60 | | |
| 29 | Dummy | 60 | | |
| 30 | Rate | 150 | 1285.66 | 3.9% |
| 31 | Rate | 150 | 1284.44 | 4.3% |

The level temperature indicates that SUBA® 500 in-situ conditioning helps to maintain a consistent removal rate between each wafer being polished. The removal rates were between 1123.98 and 1308.28 angstroms per minute (112.398 and 30.828 nanometers per minute).

### EXAMPLE 4

This example illustrates conditioning a polishing pad using a conditioning pad containing a polyurethane in the conditioning pad.

A Rodel metals 26 pad was conditioned using a Rodel JR111 polishing pad as the conditioning pad. The Rodel metals 26 pad has narrow concentric grooves cut into the polishing surface of the pad. Deionized (DI) water was added to the pad surfaces at the rate of 0.05 L/min. The down force was about 5 psi (about 35×10³ kg/m²).

Conditioning produced friction and removed material from the surface of the metals 26 pad and from the surface of the JR111 conditioning pad. The amount of material removed from the metals 26 pad was minimal compared to a diamond conditioning method. The abrasion properties of polyurethane JR111 to the polyurethane metals 26 pad produced a texture in the metals 26 pad. The friction between the JR111 conditioning polyurethane, which is harder than the metals 26 pad polyurethane, caused wear to the two materials, but less to the dominant or more abrasive resistant JR111 conditioning pad.

### EXAMPLE 5

Typical conditioning conditions are given in the following table. Table 2 shows typical conditions for primary conditioning using the head of the polisher and typical conditions for secondary conditioning (in-situ or ex-situ conditioning) using the conditioning arm of the polisher.

TABLE 2

| PRIMARY CONDITIONING METHOD | | |
|---|---|---|
| USING HEAD OF POLISHER | START UP | PROCESS |
| PLATEN/rpm: | 20 | 100 |
| HEAD/rpm: 20 | 100 | |
| HEAD OSCULATION (in) | 1 | 1 |
| HEAD STROKE RATE (spm) 30 | 30 | |
| CONDITIONING PAD UNIT | 2 | 4 |
| PRESSURE/(+/−)psi: | | |
| DI WATER FLOW RATE (Mil/min): | 1000 | 1000 |
| DI WATER TIME/seconds: 15 | 900 | |
| CONDITIONER SIZE: | 200 mm | 200 mm |
| CONDITIONING TYPE: | JR111 | JR111 |
| IN SITU/EX SITU METHOD | | |
| USING CONDITIONING ARM | | PROCESS |
| PLATEN/rpm: | | 50 |
| HEAD/rpm: | | 40 |
| HEAD OSCULATION (in) | | 1 |
| HEAD STROKE RATE (spm) | | 30 |
| CONDITIONING PAD DOWN | | 15 |
| FORCE (+/−)Ib: | | |
| SLURRY/CLEANING SOLUTION FLOW | | 200.0 |
| RATE (Mil/min): | | |
| SLURRY/CLEANING SOLUTION | | 120 |
| TIME/seconds: | | |
| CONDITIONER SIZE: | 100 mm | |
| CONDITIONING TYPE: | SUBA 500 | |

What is claimed is:

1. A method for conditioning a polishing pad comprising the steps of; pressing a conditioning surface of a conditioning pad comprising a first polymer against a polishing surface of the polishing pad comprising a second polymer, and producing relative motion between the pads such that measured characteristics of the polishing surface are changed.

2. The method of claim 1 in which the first polymer and the second polymer are polyurethanes.

3. The method of claim 1 in which the hardness of the conditioning surface is greater than or equal to the hardness of the polishing surface.

4. The method of claim 1 in which the conditioning pad comprises a urethane impregnated polyester felt.

5. The method of claim 1 in which the first polymer and the second polymer are each polymers selected from the group consisting: acrylated urethanes; acrylated epoxys; ethylenically unsaturated organic compounds having a carboxyl, benzyl, or amide functionality; aminoplast derivatives having a pendant unsaturated carbonyl group; isocyanurate derivatives having at least one pendant acrylate group; vinyl ethers; urethanes; polyacrylamides; ethylene/ester copolymers or acid derivatives thereof; polyvinyl alcohols; polymethyl methacrylates; polysulfones; polyamides; polycarbonates; polyvinyl chloride; epoxys; copolymers of the above; or combinations thereof; and in which the first polymer and the second polymer are each present as a continuous matrix.

6. The method of claim 5 in which the hardness of the conditioning surface is greater than or equal to the hardness of the polishing surface.

7. The method as recited in claim 1 wherein, the conditioning pad comprises a poromeric material comprising a porous thermoplastic matrix reinforced with a fiber network, the matrix being coalesced among the fibers to increase the porosity and hardness of the material, and wherein the matrix comprises a blend of at least two polymers, one of the polymers having a melting point higher than the other, whereby the higher melting point polymer is not substantially coalesced.

8. The method of claim 1 wherein, the polishing pad comprises a urethane polymer and the conditioning pad comprises a urethane polymer.
